(19) United States
(12) Patent Application Publication
(10) Pub. No.: US 2006/0000583 A1
(43) Pub. Date: Jan. 5, 2006

(54) Heat dissipating device

(75) Inventor: Din-Hwea Lee, Ping-Chen City (TW)

Correspondence Address: BRINKS HOFER GILSON & LIONE, P.O. BOX 10395, CHICAGO, IL, 60610, US

(73) Assignee: Great Univer Technology Co., Ltd.

(21) Appl. No.: 10/883,097

(22) Filed: Jul. 1, 2004

(51) Int. Cl. H05K 7/20

(52) U.S. Cl. 165/104.33; 361/700

(57) ABSTRACT

A heat dissipating device includes a first fluid container containing an amount of working fluid therein, a heat-conductive second fluid container placed in contact with a heat source, a first check valve unit for permitting flow of the working fluid from the first fluid container into a first accommodating space of the second fluid container via a supply pipe when a fluid pressure in the first fluid container is greater than that in the second fluid container, and a second check valve unit for permitting fluid flow from a second accommodating space of the second fluid container into the first fluid container via a return pipe when the fluid pressure in the first fluid container is less than that in the second fluid container.

### BACKGROUND OF THE INVENTION

1. Field of the Invention

The invention relates to a heat dissipating device, more particularly to a heat dissipating device that can provide an enhanced heat-dissipating effect through a heat-exchanging working fluid therein.

2. Description of the Related Art

FIG. 1 illustrates a conventional heat dissipating device 1 for dissipating heat generated by a heat-generating component 2 mounted on a circuit board 2. The conventional heat dissipating device 1 includes a heat dissipating fin unit 11 having a plurality of heat-dissipating fin plates 111 and placed in contact with the heat-generating component 21, and a fan unit 12 mounted on the heat-dissipating fin unit 11. Since the conventional heat dissipating device 1 is relatively thick, the conventional heat dissipating device 1 is not suited for application to an electronic apparatus with a reduced profile.

### SUMMARY OF THE INVENTION

Therefore, the object of the present invention is to provide a heat dissipating device that can provide an enhanced heat-dissipating effect through a heat-exchanging working fluid therein and that is suitable for low-profile applications.

According to the present invention, there is provided a heat dissipating device for dissipating heat generated by a heat source. The heat dissipating device comprises:
a first fluid container containing an amount of working fluid therein, the working fluid being capable of changing into fluid vapor when heated, the fluid vapor being capable of changing into fluid condensate when cooled, the first fluid container having a first fluid outlet and a first fluid inlet;
a second fluid container made of a heat conductive material and having a device contacting side adapted to be placed in contact with the heat source, the second fluid container confining first and second accommodating spaces that are in fluid communication with each other, and having a second fluid inlet for access into the first accommodating space, and a second fluid outlet for access into the second accommodating space;
a supply pipe interconnecting the first fluid outlet of the first fluid container and the second fluid inlet of the second fluid container;
a return pipe interconnecting the first fluid inlet of the first fluid container and the second fluid outlet of the second fluid container;
a first check valve unit for permitting flow of the working fluid from the first fluid container into the first accommodating space of the second fluid container via the supply pipe when a fluid pressure in the first fluid container is greater than that in the second fluid container; and
a second check valve unit for permitting fluid flow from the second accommodating space into the first fluid container via the return pipe when the fluid pressure in the first fluid container is less than that in the second fluid container.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of a conventional heat dissipating device;

FIG. 2 is a fragmentary perspective view showing the first preferred embodiment of a heat dissipating device according to this invention;

FIG. 3 is a perspective view showing the first preferred embodiment when installed in a computer apparatus; and

FIG. 4 is a fragmentary schematic view showing the second preferred embodiment of a heat dissipating device according to this invention.

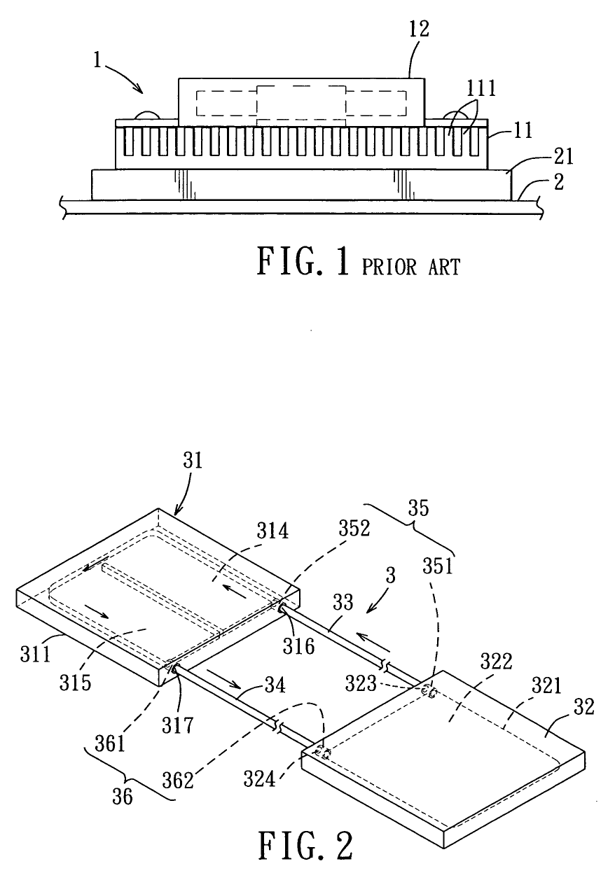

### DETAILED DESCRIPTION OF THE PREFERRED EMBODIMENTS

Before the present invention is described in greater detail, it should be noted that like elements are denoted by the same reference numerals throughout the disclosure.

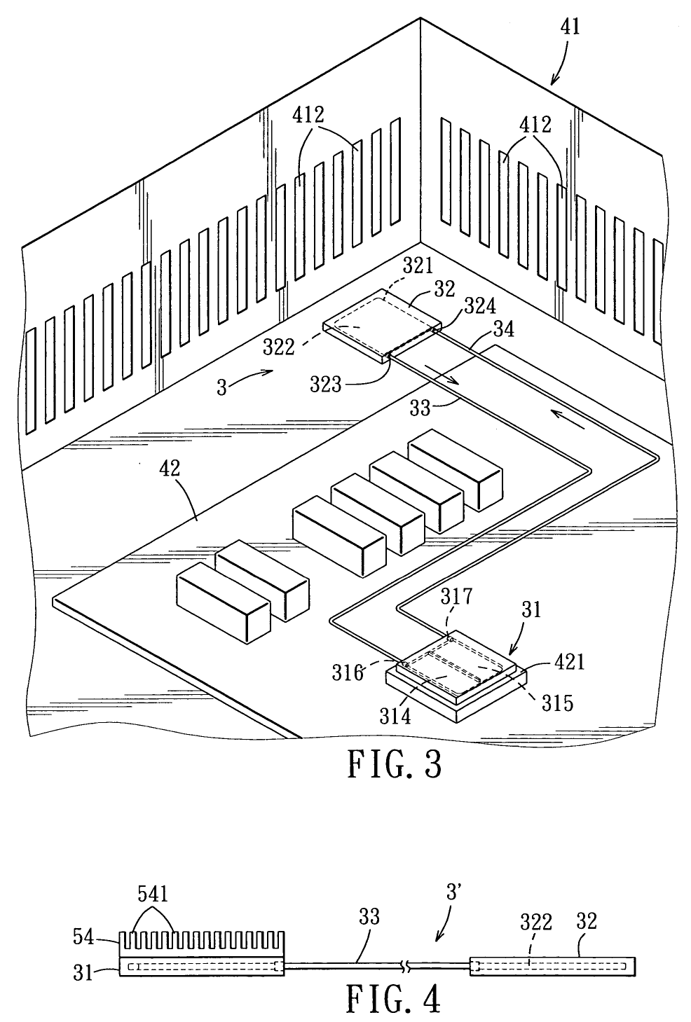

FIGS. 2 and 3 illustrate the first preferred embodiment of a heat dissipating device 3 for dissipating heat generated by a heat source according to the present invention. The heat dissipating device 3 includes a first fluid container 32, a second fluid container 31, a supply pipe 33, a return pipe 34, a first check valve unit 35, and a second check valve unit 36. In this embodiment, the heat source is an electronic component 421 mounted on a main board 42 in a computer housing 41 (see FIG. 3). The heat dissipating device 3 is adapted to be disposed in the computer housing 41.

The first fluid container 32 contains an amount of working fluid 322 therein. The working fluid 322 is capable of changing into fluid vapor when heated. The fluid vapor is capable of changing into fluid condensate when cooled. The first fluid container 32 has a first fluid outlet 323 and a first fluid inlet 324. In this embodiment, the first fluid container 32 is made of a heat conductive material, and is adapted to be disposed adjacent to a plurality of vent holes 412 in the computer housing 41. The working fluid 322 is a heat exchanging coolant.

The second fluid container 31, which is made of a heat conductive material, is substantially flat in this embodiment, and has a device contacting side 311 adapted to be placed in contact with the electronic component 421, as best shown in FIG. 3. The second fluid container 31 is partitioned into first and second accommodating spaces 314, 315 that are in fluid communication with each other, and has a second fluid inlet for 316 for access into the first accommodating space 314, and a second fluid outlet 317 for access into the second accommodating space 315.

The supply pipe 33 interconnects the first fluid outlet 323 of the first fluid container 32 and the second fluid inlet 316 of the second fluid container 31. In this embodiment, the supply pipe 33 is made of a heat conductive material.

The return pipe 34 interconnects the first fluid inlet 324 of the first fluid container 32 and the second fluid outlet 317 of the second fluid container 31. In this embodiment, the return pipe 34 is made of a heat conductive material.

The first check valve unit 35 permits flow of the working fluid 322 from the first fluid container 32 into the first accommodating space 314 of the second fluid container 31 via the supply pipe 33 when a fluid pressure in the first fluid container 32 is greater than that in the second fluid container 31. In this embodiment, the first check valve unit 35 includes two first check valves 351, 352 that are respectively provided at the first fluid outlet 323 of the first fluid container 32 and the second fluid inlet 316 of the second fluid container 31.

The second check valve unit 36 permits fluid flow from the second accommodating space 315 of the second fluid container 31 into the first fluid container 32 via the return pipe 34 when the fluid pressure in the first fluid container 32 is less than that in the second fluid container 31. In this embodiment, the second check valve unit 36 includes two second check valves 361, 362 that are respectively provided at the second fluid outlet 317 of the second fluid container 31 and the first fluid inlet 324 of the first fluid container 32.

FIG. 4 illustrates the second preferred embodiment of a heat dissipating device 3′ according to this invention, which is a modification of the first preferred embodiment. In this embodiment, the heat dissipating device 3′ further includes a heat dissipating fin unit 54 mounted on the second fluid container 31 and having a plurality of heat-dissipating fin plates 541.

To sum up, due to the supply and return pipes 33, 34 and the first and second check valve units 35, 36, the heat dissipating device 3, 3′ of this invention can achieve an enhanced heat dissipating effect through a heat-exchanging the working fluid 322 therein, the working fluid 322 being circulated as a result of a fluid pressure difference between the first and second fluid containers 32, 31. Furthermore, since a fan unit is not required, the heat dissipating device 3, 3′ of this invention is relatively thin and is thus suitable for low-profile applications.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A heat dissipating device for dissipating heat generated by a heat source, comprising:
a substantially flat first fluid container containing an amount of working fluid therein, said working fluid being capable of changing into fluid vapor when heated, said fluid vapor being capable of changing into fluid condensate when cooled, said first fluid container having a first fluid outlet and a first fluid inlet;
a substantially flat second fluid container made of a heat conductive material and having a device contacting side adapted to be placed in contact with the heat source, said second fluid container confining first and second accommodating spaces that are in fluid communication with each other, and having a second fluid inlet for access into said first accommodating space, and a second fluid outlet for access into said second accommodating space;
a supply pipe interconnecting said first fluid outlet of said first fluid container and said second fluid inlet of said second fluid container;
a return pipe interconnecting said first fluid inlet of said first fluid container and said second fluid outlet of said second fluid container;
a first check valve unit for permitting flow of said working fluid from said first fluid container into said first accommodating space of said second fluid container via said supply pipe when a fluid pressure in said first fluid container is greater than that in said second fluid container; and
a second check valve unit for permitting fluid flow from said second accommodating space into said first fluid container via said return pipe when the fluid pressure in said first fluid container is less than that in said second fluid container.

2. (canceled)

3. The heat dissipating device as claimed in claim 1, wherein said working fluid is a heat exchanging coolant.

4. The heat dissipating device as claimed in claim 1, further comprising a heat dissipating fin unit mounted on said second fluid container.

5. The heat dissipating device as claimed in claim 1, wherein said first fluid container is made of a heat conductive material.

6. The heat dissipating device as claimed in claim 1, wherein said supply and return pipes are made of a heat conductive material.
